(19) United States
(12) Patent Application Publication
(10) Pub. No.: US 2026/0180591 A1
(43) Pub. Date: Jun. 25, 2026

(54) Analog to Digital Conversion Circuit, Chip, and Electronic Apparatus

(71) Applicant: Tsinghua University, Beijing (CN)

(72) Inventors: Yi ZHONG, Beijing (CN); Mingyang GU, Beijing (CN); Lu JIE, Beijing (CN); Nan SUN, Beijing (CN)

(21) Appl. No.: 19/426,821

(22) Filed: Dec. 19, 2025

(30) Foreign Application Priority Data
Dec. 24, 2024 (CN) 202411919200.7
Dec. 24, 2024 (CN) 202411919203.0
Dec. 24, 2024 (CN) 202411919623.9

(51) Int. Cl. H03M 1/18

(52) U.S. Cl. CPC H03M 1/181

(57) ABSTRACT

The present disclosure relates to the field of analog to digital conversion, and provides an analog to digital conversion circuit, a chip and electronic apparatus. The circuit comprises a clock signal generator, a converter, and a feedback circuit, wherein a power supply voltage of the clock signal generator, the converter, and the feedback circuit is less than or equal to a first threshold, the clock signal generator configured to generate at least one pair of clock signals with a swing greater than the first threshold, and output the clock signals to the converter to drive at least a part of the converter, the converter configured to obtain a digital output signal based on an analog input signal and a feedback signal, and the feedback circuit configured to generate the feedback signal based on a latest digital output signal and output the feedback signal to the converter.

### CROSS-REFERENCE TO RELATED APPLICATION

The present application claims priority to Chinese Patent Application No. 202411919623.9, filed Dec. 24, 2024, and entitled “Clock signal bootstrap circuit, cascade circuit, chip and electronic apparatus”, Chinese Patent Application No. 202411919203.0, filed Dec. 24, 2024, and entitled “Analog-to-digital conversion circuit based on clock signal bootstrap circuit, chip and electronic apparatus”, and Chinese Patent Application No. 202411919200.7, filed Dec. 24, 2024, and entitled “Analog-to-digital conversion circuit based on boost circuit, chip and electronic apparatus”, the entire contents of which are incorporated herein by reference.

### TECHNICAL FIELD

The present disclosure relates to the field of analog to digital conversion, and in particular, to an analog to digital conversion circuit, a chip, and an electronic apparatus.

### BACKGROUND

With the application and development of Internet of Things (IoT), obtaining real-time information and data from IoT devices becomes helpful. The power supply of the IoT device is an important aspect in the design of the IoT system, because it directly affects the reliability, durability and cost of the device. Power supply manners of the IoT device generally include battery power supply, solar power supply, cable power supply, wireless charging, and energy harvesting (EH). Among them, the energy harvesting refers to using ambient energy, such as solar energy, wind energy, mechanical vibration, or temperature difference, to supply power and reduce dependence on a battery.

However, in some environments, the density of energy that can be harvested is often relatively low, and the voltage that can be generated is also very low, so that the IoT device must operate at a low voltage. This brings great challenges to the performance of some circuits (e.g., analog to digital conversion circuits) in IoT devices. Some analog to digital conversion circuits proposed in the prior art cannot maintain higher-quality analog to digital conversion when the supply voltage is a low voltage, and although some analog to digital conversion circuits proposed in the prior art can maintain higher-quality analog to digital conversion when the supply voltage is a low voltage, power consumption of the analog to digital conversion circuit is greatly increased.

### SUMMARY

In view of this, the present disclosure provides an analog to digital conversion circuit, a chip, and an electronic apparatus. The analog to digital conversion circuit of an embodiment of the present disclosure has relatively low power consumption and can realize high-quality analog to digital conversion at a low voltage.

According to an aspect of the present disclosure, there is provided an analog to digital conversion circuit, comprising a clock signal generator, a converter, and a feedback circuit, wherein a power supply voltage of the clock signal generator, the converter, and the feedback circuit is less than or equal to a first threshold, the clock signal generator configured to generate at least one pair of clock signals with a swing greater than the first threshold, and output the clock signals to the converter to drive at least a part of the converter; the converter configured to obtain a digital output signal based on an analog input signal and a feedback signal; and the feedback circuit configured to generate the feedback signal based on a latest digital output signal and output the feedback signal to the converter.

In a possible implementation, the converter comprises a first chopping part, a capacitor filtering part, a dead zone control part, a voltage-current conversion part, a second chopping part, an integration part, a quantization part, and an output part, the analog input signal comprises differential first input signal and second input signal, and the feedback signal comprises differential first feedback signal and second feedback signal; a first terminal of the first chopping part receives the first input signal, a second terminal of the first chopping part receives the second input signal, a third terminal of the first chopping part is connected to a first terminal of the capacitor filtering part, and a fourth terminal of the first chopping part is connected to a second terminal of the capacitor filtering part, a third terminal of the capacitor filtering part is connected to a first terminal of the dead zone control part and a fourth terminal of the feedback circuit, the fourth terminal of the capacitor filtering part is connected to a second terminal of the dead zone control part and a third terminal of the feedback circuit, the fourth terminal of the feedback circuit outputs the first feedback signal, and the third terminal of the feedback circuit outputs the second feedback signal; a third terminal of the dead zone control part is connected to a first terminal of the voltage-current conversion part, and a fourth terminal of the dead zone control part is connected to a second terminal of the voltage-current conversion part; a third terminal of the voltage-current conversion part is connected to a first terminal of the second chopping part; and a fourth terminal of the voltage-current conversion part is connected to a second terminal of the second chopping part; a third terminal of the second chopping part is connected to the first terminal of the integration part; and a fourth terminal of the second chopping part is connected to the second terminal of the integration part; a third terminal of the integration part is connected to a first terminal of the quantization part, a fourth terminal of the integration part is connected to a second terminal of the quantization part, the third terminal of the quantization part is connected to a first terminal of the output part and a first terminal of the feedback circuit, and the fourth terminal of the quantization part is connected to a second terminal of the output part and a second terminal of the feedback circuit, and a third terminal of the output part outputs the digital output signal.

In a possible implementation, the quantization part is a time domain quantization part, the integration part is a time domain integration part, and the quantization part and the integration part are implemented by using a digital circuit.

In a possible implementation, the clock signal is configured to driving the first chopping part, the dead zone control part, and the second chopping part.

In a possible implementation, the clock signal generator includes at least one cascaded clock signal bootstrap circuit, each clock signal bootstrap circuit outputs a pair of clock signals, a clock signal output by a previous-stage clock signal bootstrap circuit is used as a clock signal input by a post-stage clock signal bootstrap circuit, and a swing of the clock signal output by the post-stage clock signal bootstrap circuit is higher than a swing of the clock signal output by the previous-stage clock signal bootstrap circuit.

In a possible implementation, a swing of a clock signal used to drive the dead zone control part is greater than or equal to a second threshold, a swing of a clock signal used to drive the first chopping part and the second chopping part is greater than or equal to a third threshold, and the second threshold is greater than the third threshold.

In a possible implementation, the feedback circuit comprises a logic control part, a third chopping part, and a capacitive digital to analog conversion part, a first terminal of the logic control part is used as the first terminal of the feedback circuit, a second terminal of the logic control part is used as the second terminal of the feedback circuit, a third terminal of the logic control part is connected to the first terminal of the third chopping part, and a fourth terminal of the logic control part is connected to the second terminal of the third chopping part; a third terminal of the third chopping part is connected to the first terminal of the capacitive digital to analog conversion part, and a fourth terminal of the third chopping part is connected to the second terminal of the capacitive digital to analog conversion part; and a third terminal of the capacitive digital to analog conversion part is used as the third terminal of the feedback circuit, and a fourth terminal of the capacitive digital to analog conversion part is used as the fourth terminal of the feedback circuit.

In a possible implementation, the clock signal bootstrap circuit comprises a first bootstrap sub-circuit and a second bootstrap sub-circuit, the first bootstrap sub-circuit comprises a first transistor, a second transistor, a third transistor, and a first capacitor, and the second bootstrap sub-circuit comprises a fourth transistor, a fifth transistor, a sixth transistor and a second capacitor, a first pole of the first transistor is connected to a first pole of the second transistor and is used as a first input terminal of the first bootstrap sub-circuit, a second pole of the first transistor is connected to a first terminal of the first capacitor and is used as a second input terminal of the first bootstrap sub-circuit, a third pole of the first transistor is connected to a third pole of the second transistor and a first pole of the third transistor and is used as an output terminal of the first bootstrap sub-circuit, a second pole of the second transistor is connected to a second pole of the third transistor and a second terminal of the first capacitor, and a third pole of the third transistor is connected to a power supply voltage; a first pole of the fourth transistor is connected to a first pole of the fifth transistor and is used as a first input terminal of the second bootstrap sub-circuit, a second pole of the fourth transistor is connected to a first terminal of the second capacitor and is used as a second input terminal of the second bootstrap sub-circuit, a third pole of the fourth transistor is connected to a third pole of the fifth transistor and a first pole of the sixth transistor and is used as an output terminal of the second bootstrap sub-circuit, a second pole of the fifth transistor is connected to a second pole of the sixth transistor and a second terminal of the second capacitor, and a third pole of the sixth transistor is connected to a power supply voltage; a first input terminal of the second bootstrap sub-circuit is connected to a second input terminal of the first bootstrap sub-circuit to receive a first clock signal, a second input terminal of the second bootstrap sub-circuit is connected to the first input terminal of the first bootstrap sub-circuit to receive a second clock signal, an output terminal of the first bootstrap sub-circuit outputs a third clock signal, and an output terminal of the second bootstrap sub-circuit outputs a fourth clock signal; and the first clock signal and the second clock signal are a pair of differential signals and are used as clock signals input by the clock signal bootstrap circuit, and the third clock signal and the fourth clock signal are a pair of differential signals being clock signals output by the clock signal bootstrap circuit.

In a possible implementation, the circuit further comprises an inverter, an input terminal of the inverter is connected to the second input terminal of the first bootstrap sub-circuit and the first input terminal of the second bootstrap sub-circuit, an output terminal of the inverter is connected to the first input terminal of the first bootstrap sub-circuit and the second input terminal of the second bootstrap sub-circuit, and the second clock signal is generated by the inverter.

In a possible implementation, based on that the first clock signal is at a low level, the second pole and the third pole of the first transistor conduct, the second pole and the third pole of the third transistor conduct, the second pole and the third pole of the second transistor do not conduct and the gate-source voltage is greater than or equal to 0, the power supply voltage charges the first capacitor through the third transistor, and the third clock signal is at a low level; when the first clock signal is at a high level, the second pole and the third pole of the first transistor do not conduct and the gate-source voltage is less than 0, the second pole and the third pole of the third transistor do not conduct, the second pole and the third pole of the second transistor conduct, the first capacitor is discharged, the third clock signal is at a high level and the level of the third clock signal is greater than the level of the first clock signal; based on that the high level of the first clock signal is equal to the power supply voltage, when the second pole and the third pole of the second transistor do not conduct, the gate-source voltage of the second transistor is equal to 0; and in the case that the high level of the first clock signal is greater than the power supply voltage, when the second pole and the third pole of the second transistor do not conduct, the gate-source voltage of the second transistor is greater than 0.

In a possible implementation, when the second clock signal is at a low level, the second pole and the third pole of the fourth transistor conduct, the second pole and the third pole of the sixth transistor conduct, the second pole and the third pole of the fifth transistor do not conduct and the gate-source voltage is greater than or equal to 0, the power supply voltage charges the second capacitor through the sixth transistor, and the fourth clock signal is at a low level; when the second clock signal is at a high level, the second pole and the third pole of the fourth transistor do not conduct and the gate-source voltage is less than 0, the second pole and the third pole of the sixth transistor do not conduct, the second pole and the third pole of the fifth transistor conduct, the second capacitor is discharged, the fourth clock signal is at a high level and the level of the fourth clock signal is greater than the level of the second clock signal; in the case that the high level of the second clock signal is equal to the power supply voltage, when the second pole and the third pole of the fifth transistor do not conduct, the gate-source voltage of the fifth transistor is equal to 0; and in the case that the high level of the second clock signal is greater than the power supply voltage, when the second pole and the third pole of the fifth transistor do not conduct, the gate-source voltage of the fifth transistor is greater than 0.

In a possible implementation, the clock signal generator comprises a boost sub-circuit and a clock buffer sub-circuit, the boost sub-circuit configured to generate at least one voltage signal whose voltage value is greater than the power supply voltage, and the voltage signals configured to supply power to the clock buffer sub-circuit; and the clock buffer sub-circuit configured to generate at least one pair of clock signals with a swing greater than the first threshold, and output the clock signals to the converter to drive at least a part of the converter.

In a possible implementation, the boost sub-circuit comprises a plurality of DCDC converters, the power supply voltage is input to the plurality of DCDC converters respectively, the clock buffer sub-circuit comprises a plurality of clock buffers, and each DCDC converter is connected to one clock buffer, each DCDC converter boosts an input voltage signal to obtain a boosted voltage signal, and outputs the boosted voltage signal to a clock buffer connected to the DCDC converter, and each clock buffer generates and outputs a pair of clock signals based on the received voltage signal.

In a possible implementation, the boost sub-circuit comprises a DCDC converter, the clock buffer sub-circuit comprises a clock buffer, and the DCDC converter is connected to the clock buffer, the DCDC converter boosts an input voltage signal to obtain a boosted voltage signal and outputs the boosted voltage signal to the clock buffer, and the clock buffer generates and outputs a pair of clock signals based on a received voltage signal.

According to another aspect of the present disclosure, a chip is provided, including the analog to digital conversion circuit according to any one of the above.

According to another aspect of the present disclosure, an electronic apparatus is provided, including the chip described above.

According to the analog to digital conversion circuit of the embodiment of the present disclosure, by providing the clock signal generator, the clock signal with the swing higher than the first threshold can be obtained under the condition that the power supply voltage lower than the first threshold is supplied, the converter is driven by the clock signal with the higher swing, the converter obtains the digital output signal according to the analog input signal and the feedback signal, and the feedback circuit generates the feedback signal according to the latest digital output signal and outputs the feedback signal to the converter, thereby realizing high-quality analog to digital conversion. In the analog to digital conversion circuit, only some parts in the converter are driven by a high-swing clock signal, and other parts of the converter, the clock signal generator, and the feedback circuit may still be powered by a power supply voltage lower than the first threshold, so that the overall power consumption of the analog to digital conversion circuit is relatively low. In summary, the analog to digital conversion circuit of an embodiment of the present disclosure has relatively low power consumption, and can realize high-quality analog to digital conversion at a low voltage.

Other features and aspects of the present disclosure will become apparent from the following detailed description of exemplary embodiments with reference to the accompanying drawings.

### BRIEF DESCRIPTION OF THE DRAWINGS

The accompanying drawings, which are incorporated in and constitute a part of this specification, illustrate exemplary embodiments, features, and aspects of the present disclosure and, together with the specification, serve to explain the principles of the disclosure.

FIG. 1 shows a schematic diagram of an energy harvesting system supplying power to a circuit in an IoT device.

FIG. 2 shows an operating scheme of the ADC when the supply voltage is relatively low.

FIG. 3 illustrates another operating scheme of the ADC when the supply voltage is relatively low.

FIG. 4 illustrates an exemplary application scenario of an analog to digital conversion circuit according to an embodiment of the present disclosure.

FIG. 5 shows a schematic diagram of a structure of an analog to digital conversion circuit according to an embodiment of the present disclosure.

FIG. 6 shows a schematic diagram of a structure of a clock signal generator according to an embodiment of the present disclosure.

FIG. 7 shows a schematic diagram of a structure of a clock signal bootstrap circuit according to an embodiment of the present disclosure.

FIG. 8 shows a schematic diagram of another structure of a clock signal bootstrap circuit according to an embodiment of the present disclosure.

FIG. 9 shows a schematic diagram of a structure of a clock signal generator according to an embodiment of the present disclosure.

FIG. 10 shows a schematic diagram of structures of a boost sub-circuit and a clock buffer sub-circuit according to an embodiment of the present disclosure.

FIG. 11 shows a schematic diagram of structures of a boost sub-circuit and a clock buffer sub-circuit according to an embodiment of the present disclosure.

FIG. 12a shows a schematic diagram of a structure of a converter according to an embodiment of the present disclosure.

FIG. 12b shows a schematic diagram of a structure of a converter according to an embodiment of the present disclosure.

FIG. 13 shows a schematic diagram of a structure of a feedback circuit according to an embodiment of the present disclosure.

### DETAILED DESCRIPTION

Various exemplary embodiments, features and aspects of the present disclosure will be described in detail below with reference to the accompanying drawings. The same reference numbers in the drawings indicate functionally the same or similar elements. While the various aspects of the embodiments are presented in drawings, the drawings are not necessarily drawn to scale unless specifically indicated.

The word “exemplary” is used exclusively herein to mean “serving as an example, embodiment, or illustration”. Any embodiment described herein as “exemplary” is not necessarily to be construed as preferred or advantageous over other embodiments.

In addition, in order to better illustrate the present disclosure, numerous specific details are given in the following specific embodiments. It will be understood by those skilled in the art that the present disclosure may be implemented without some of the specific details. In some instances, methods, means, elements and circuits well known to those skilled in the art are not described in detail, so as to highlight the subject matter of the present disclosure.

FIG. 1 shows a schematic diagram of an energy harvesting system supplying power to a circuit in an IoT device.

As shown in FIG. 1, the energy harvesting system may harvest energy from an external energy source, convert the energy into a supply voltage (VDD), and output the supply voltage to a data transceiver circuit, a digital signal processor (DSP), an analog to digital converter (ADC), and the like in the IoT device. The energy density harvested by the energy harvesting system is often less than 100 uW/cm², and its corresponding output voltage is generally less than 300 mV. The voltage supplies power to an ADC, a DSP, a data transceiver circuit, and the like in the system. Achieving high-quality analog to digital conversion at such low voltages is very difficult for ADCs.

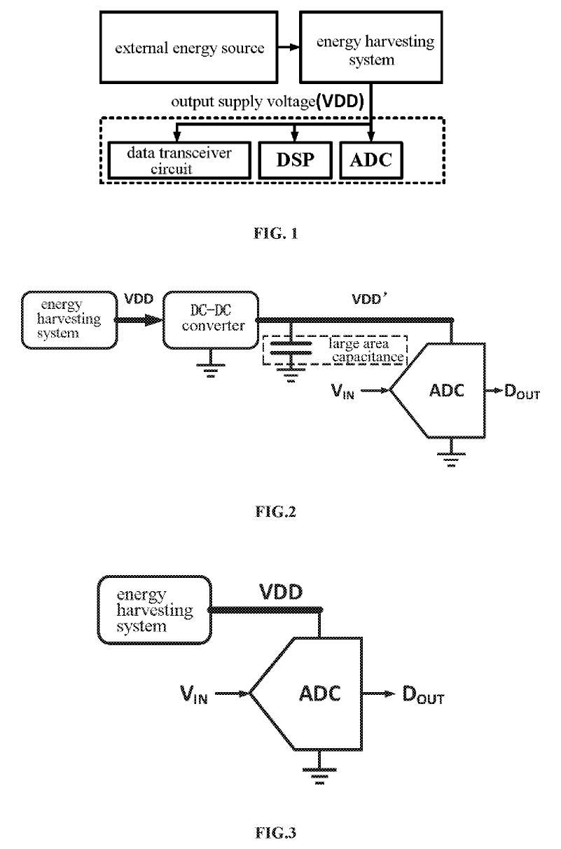

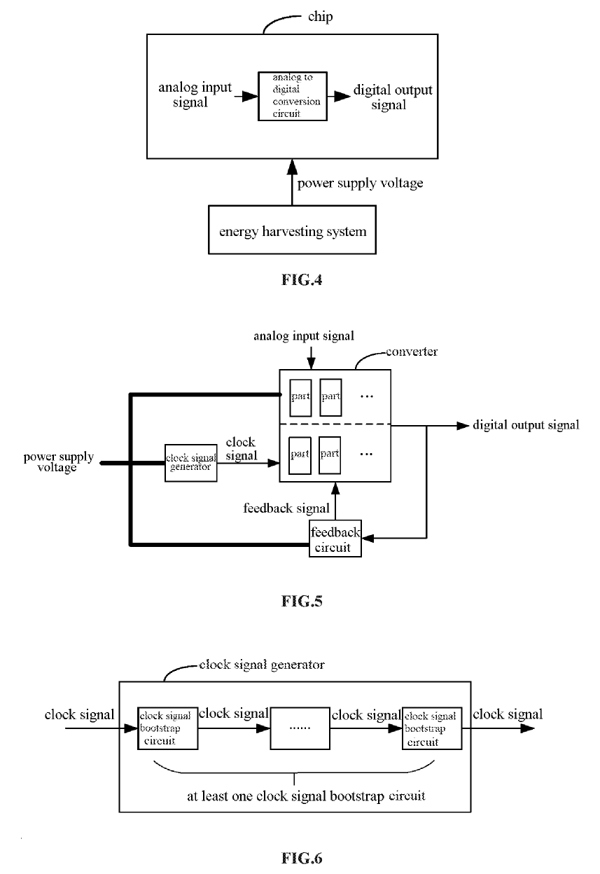

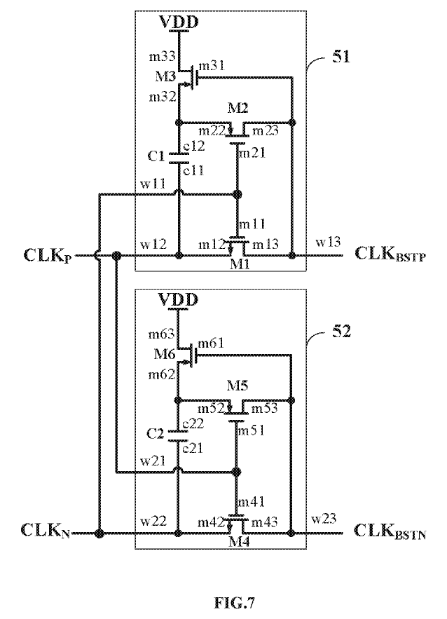

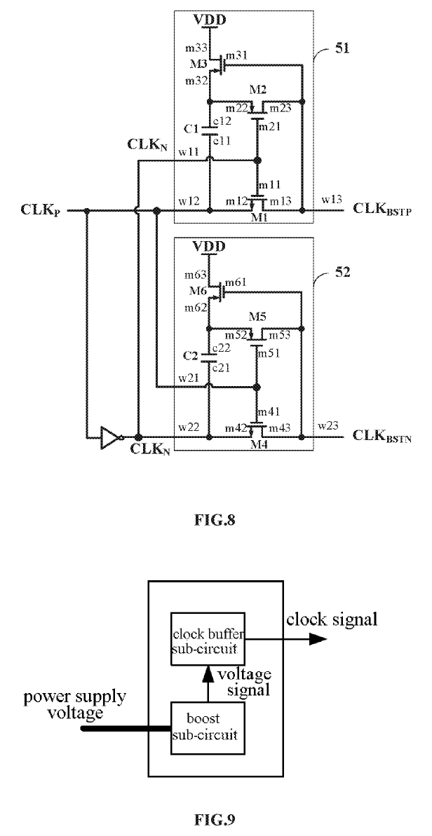

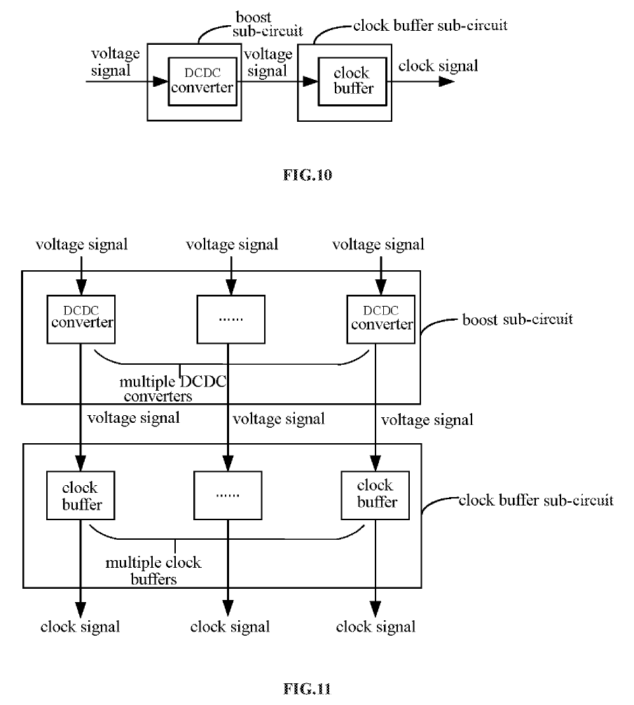

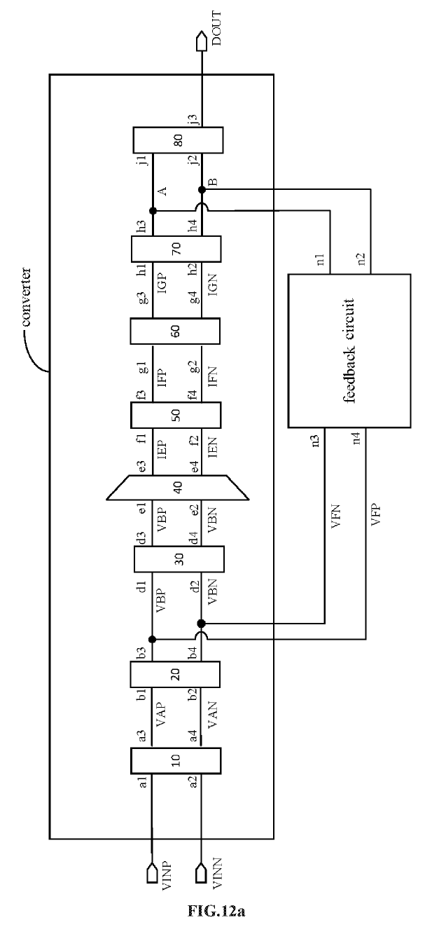

FIG. 2 shows an operating scheme of the ADC when the supply voltage is relatively low.

As shown in FIG. 2, a DC-DC converter may be used to directly increase a low voltage VDD output by the energy harvesting system to a high voltage VDD′ that can enable the ADC to operate normally, and then the high voltage VDD′ is provided to the ADC as a supply voltage, and the ADC converts an input analog signal V_{IN} into a digital signal D_{OUT} and outputs the digital signal D_{OUT}. However, the overall power consumption of the ADC is greatly increased. In addition, the voltage signal output by the DC-DC converter is provided to the whole ADC as the supply voltage, so a capacitor with a very large area needs to be additionally added on the chip for storing charges, which increases the chip area, thereby increasing the cost of the chip.

FIG. 3 illustrates another operating scheme of the ADC when the supply voltage is relatively low.

As shown in FIG. 3, another method is to use some ADCs that can still operate normally at a low voltage, such as an oversampling ADC based on an inverter amplifier, an oversampling ADC based on a ring oscillator, and a Successive Approximation Register (SAR) ADC based on a carefully designed comparator, to directly implement analog to digital conversion at a low voltage VDD output by an energy harvesting system, convert an input analog signal V_{IN} into a digital signal D_{OUT}, and output the digital signal D_{OUT}. However, the circuits in these ADCs are often very sensitive to the supply voltage, and the analog to digital conversion quality fluctuates greatly. The analog to digital conversion quality of these ADCs at low voltages, such as conversion linearity, conversion accuracy and other indicators, are significantly different from the ADCs that perform analog to digital conversion at normal voltages.

In summary, some analog to digital conversion circuits proposed in the prior art cannot maintain higher-quality analog to digital conversion when the supply voltage is a low voltage, and some analog to digital conversion circuits proposed in the prior art can maintain higher-quality analog to digital conversion when the supply voltage is a low voltage, but will increase the power consumption of the analog to digital conversion circuit and the occupied chip area. How to reduce the power consumption of the analog to digital conversion circuit and the occupied chip area and maintain high-quality analog to digital conversion has become a technical problem to be solved urgently in the art.

In view of this, the present disclosure provides an analog to digital conversion circuit, a chip, and an electronic apparatus. The analog to digital conversion circuit of an embodiment of the present disclosure has relatively low power consumption and can realize high-quality analog to digital conversion at a low voltage.

Further, the analog to digital conversion circuit of an embodiment of the present disclosure occupies a smaller chip area, which can save hardware costs.

FIG. 4 illustrates an exemplary application scenario of an analog to digital conversion circuit according to an embodiment of the present disclosure.

As shown in FIG. 4, the electronic apparatus may include an energy harvesting system and a chip. The analog to digital conversion circuit of an embodiment of the present disclosure may be provided on a chip. The energy harvesting system may power the chip. A value of the power supply voltage output by the energy harvesting system may be less than the first threshold, that is, the energy harvesting system outputs an ultra-low voltage. A value of the first threshold may be set according to an application scenario requirement, for example, set to 0.3 V. A specific value of the first threshold is not limited in the embodiments of the present disclosure.

The analog to digital conversion circuit may receive a to-be-converted analog input signal, perform analog to digital conversion to obtain a digital output signal, and then output the digital output signal.

A data transceiver circuit (not shown), a digital signal processor (not shown), and the like may be further provided on the chip. The analog input signal may be a signal received by the data transceiver circuit, and then transmitted by the data transceiver circuit to the analog to digital conversion circuit. The digital output signal may be output to the digital signal processor for processing, or may be transmitted to the data transceiver circuit, and transmitted by the data transceiver circuit to other devices/circuits, which is not limited in the embodiments of the present disclosure.

Those skilled in the art should understand that if the electronic apparatus itself carries a power supply, the chip can also be powered by the power supply, and when the power supply is insufficient and outputs a voltage signal with a voltage value less than the first threshold, the analog to digital conversion circuit on the chip can also realize high-quality analog to digital conversion. The embodiments of the present disclosure do not limit the power source of the chip.

FIG. 5 shows a schematic diagram of a structure of an analog to digital conversion circuit according to an embodiment of the present disclosure.

As shown in FIG. 5, in a possible implementation, the circuit includes a clock signal generator, a converter, and a feedback circuit, a power supply voltage of the clock signal generator, the converter and the feedback circuit is less than or equal to a first threshold,

the clock signal generator configured to generate at least one pair of clock signals with a swing greater than a first threshold, and output the clock signals to the converter to drive at least a part of the converter;

the converter used for obtain a digital output signal according to the analog input signal and the feedback signal;

the feedback circuit used for generate a feedback signal according to the latest digital output signal and output the feedback signal to the converter.

For example, the analog to digital conversion circuit may include a clock signal generator, a converter, and a feedback circuit, and the three circuits are powered by a power supply voltage less than a first threshold.

The clock signal generator may generate at least one pair of clock signals with a swing greater than a first threshold, and output the clock signals to the converter to drive at least a part of the converter. Each pair of clock signals includes two clock signals that are differential. The converter may include a plurality of parts, and some key parts may maintain higher performance under driving of a clock signal with a high swing. In this case, the clock signal generated by the clock signal generator may be used to drive the key parts.

The specific structures of the clock signal generator and the converter are not limited in an embodiment of the present disclosure, as long as the clock signal generator and the converter can achieve the above functions. Examples of the structure of the clock signal generator, the structure of the converter, and the key part are given below.

The analog to digital conversion process may include three main stages of voltage-current conversion, integration, and quantization, all of which may be completed by the converter. Before the analog input signal enters the voltage-current conversion stage, it can also undergo operations such as chopping to optimize the signal quality. When the voltage-current conversion operation is performed, the higher the swing of the analog input signal, the larger the deviation of the finally obtained digital output signal. Therefore, the converter may adjust the swing of the analog input signal by using the feedback signal, and then perform operations such as voltage-current conversion, integration, and quantization on the adjusted analog input signal, to obtain the digital output signal.

The analog input signal is periodically input to the converter, so the converter may output the digital output signal more than once. The feedback signal may be generated by the feedback circuit according to the latest digital output signal. In this way, the accuracy of adjusting the analog to digital conversion process using the feedback signal can be improved. The specific structure of the feedback circuit is not limited in the embodiments of the present disclosure, as long as the feedback circuit can achieve the above functions. An example of the structure of the feedback circuit is given below.

According to the analog to digital conversion circuit of the embodiment of the present disclosure, by providing the clock signal generator, the clock signal with the swing higher than the first threshold can be obtained under the condition that the power supply voltage lower than the first threshold is supplied, the converter is driven by the clock signal with the higher swing, the converter obtains the digital output signal according to the analog input signal and the feedback signal, and the feedback circuit generates the feedback signal according to the latest digital output signal and outputs the feedback signal to the converter, thereby realizing high-quality analog to digital conversion. In the analog to digital conversion circuit, only some parts in the converter are driven by a high-swing clock signal, and other parts of the converter, the clock signal generator, and the feedback circuit may still be powered by a power supply voltage lower than the first threshold, so that the overall power consumption of the analog to digital conversion circuit is relatively low. In summary, the analog to digital conversion circuit of an embodiment of the present disclosure has relatively low power consumption, and can realize high-quality analog to digital conversion at a low voltage.

FIG. 6 shows a schematic diagram of a structure of a clock signal generator according to an embodiment of the present disclosure.

As shown in FIG. 6, in a possible implementation, the clock signal generator includes at least one cascaded clock signal bootstrap circuit, each clock signal bootstrap circuit outputs a pair of clock signals, a clock signal output by a previous-stage clock signal bootstrap circuit is used as a clock signal input by a post-stage clock signal bootstrap circuit, and a swing of the clock signal output by the post-stage clock signal bootstrap circuit is higher than a swing of the clock signal output by the previous-stage clock signal bootstrap circuit.

For example, the clock signal bootstrap circuit can increase the swing of the clock signal. If the swing of the clock signal obtained by a single clock signal bootstrap circuit can meet the driving requirement, the clock signal generator only includes one clock signal bootstrap circuit. If the swing of the clock signal obtained by a single clock signal bootstrap circuit cannot meet the driving requirement, the clock signal generator may include a plurality of cascaded clock signal bootstrap circuits, each clock signal bootstrap circuit outputs a pair of clock signals, and the clock signal output by the previous-stage clock signal bootstrap circuit is used as the clock signal input by the post-stage clock signal bootstrap circuit. Since the clock signal bootstrap circuit can increase the swing of the clock signal, the swing of the clock signal output by the post-stage clock signal bootstrap circuit is higher than the swing of the clock signal output by the previous-stage clock signal bootstrap circuit.

The circuit structure of the clock signal bootstrap circuit at each stage may be the same or different. The embodiments of the present disclosure do not limit the specific structure of each stage of clock signal bootstrap circuit, as long as the number of clock signals output by the previous-stage clock signal bootstrap circuit is consistent with the number of clock signals input by the post-stage clock signal bootstrap circuit.

The high level of the first clock signal received by the first-stage clock signal bootstrap circuit may be equal to the power supply voltage, and the high level of the first clock signal received by the second-stage and subsequent clock signal bootstrap circuits may be greater than the power supply voltage. Ideally, the high level of the clock signal output by the k-th stage (k is a positive integer) clock signal bootstrap circuit may be equal to k+1 times the power supply voltage.

In this manner, the clock signal generator can output a clock signal that meets an application scenario requirement.

FIG. 7 shows a schematic diagram of a structure of a clock signal bootstrap circuit according to an embodiment of the present disclosure.

As shown in FIG. 7, in a possible implementation, the clock signal bootstrap circuit includes a first bootstrap sub-circuit 51 and a second bootstrap sub-circuit 52, the first bootstrap sub-circuit 51 includes a first transistor M1, a second transistor M2, a third transistor M3, and a first capacitor C1, and the second bootstrap sub-circuit 52 includes a fourth transistor M4, a fifth transistor M5, a sixth transistor M6, and a second capacitor C2,

the first pole m11 of the first transistor is connected to the first pole m21 of the second transistor and is used as the first input terminal w11 of the first bootstrap sub-circuit, the second pole m12 of the first transistor is connected to the first terminal c11 of the first capacitor and is used as the second input terminal w12 of the first bootstrap sub-circuit, the third pole m13 of the first transistor is connected to the third pole m23 of the second transistor and the first pole m31 of the third transistor and is used as the output terminal w13 of the first bootstrap sub-circuit, the second pole m22 of the second transistor is connected to the second pole m32 of the third transistor and the second terminal c12 of the first capacitor, and the third pole m33 of the third transistor is connected to the power supply voltage VDD;

a first pole m41 of the fourth transistor is connected to a first pole m51 of the fifth transistor and is used as a first input terminal w21 of the second bootstrap sub-circuit, a second pole m42 of the fourth transistor is connected to a first terminal c21 of the second capacitor and is used as a second input terminal w22 of the second bootstrap sub-circuit, a third pole m43 of the fourth transistor is connected to a third pole m53 of the fifth transistor and a first pole m61 of the sixth transistor and is used as an output terminal w23 of the second bootstrap sub-circuit, a second pole m52 of the fifth transistor is connected to a second pole m62 of the sixth transistor and a second terminal c22 of the second capacitor, and a third pole m63 of the sixth transistor is connected to the power supply voltage VDD;

the first input terminal w21 of the second bootstrap sub-circuit is connected to the second input terminal w12 of the first bootstrap sub-circuit to receive the first clock signal CLK_{P}, the second input terminal w22 of the second bootstrap sub-circuit is connected to the first input terminal w11 of the first bootstrap sub-circuit to receive the second clock signal CLK_{N}, the output terminal w13 of the first bootstrap sub-circuit outputs the third clock signal CLK_{BSTP}, and the output terminal w23 of the second bootstrap sub-circuit outputs the fourth clock signal CLK_{BSTN};

the first clock signal CLK_{P} and the second clock signal CLK_{N} are a pair of differential signals and are used as clock signals input by the clock signal bootstrap circuit, and the third clock signal CLK_{BSTP} and the fourth clock signal CLK_{BSTN} are a pair of differential signals being clock signals output by the clock signal bootstrap circuit.

For example, the clock signal bootstrap circuit may include a first bootstrap sub-circuit and a second bootstrap sub-circuit. The first bootstrap sub-circuit may include a first transistor, a second transistor, a third transistor, and a first capacitor. The second bootstrap sub-circuit may include a fourth transistor, a fifth transistor, a sixth transistor, and a second capacitor. The first transistor may be an N-channel transistor and the second and third transistors may be P-channel transistors. The fourth transistor may be an N-channel transistor and the fifth and sixth transistors may be P-channel transistors. The first pole of each transistor may be a gate, the second pole may be a source, and the third pole may be a drain.

Since the signal received by the first input terminal of the first bootstrap sub-circuit is the same as the signal received by the second input terminal of the second bootstrap sub-circuit, the first input terminal of the first bootstrap sub-circuit may be connected to the second input terminal of the second bootstrap sub-circuit and collectively serve as one input terminal of the clock signal bootstrap circuit. Since the signal received by the second input terminal of the first bootstrap sub-circuit is the same as the signal received by the first input terminal of the second bootstrap sub-circuit, the second input terminal of the first bootstrap sub-circuit may be connected to the first input terminal of the second bootstrap sub-circuit and jointly serve as the other input terminal of the clock signal bootstrap circuit. The output terminal of the first bootstrap sub-circuit and the output terminal of the second bootstrap sub-circuit may respectively serve as two output terminals of the clock signal generator.

The first clock signal CLK_{P} may be a low swing clock signal input outside the clock signal generator, and its voltage value may be 0 to V_{clk}. V_{clk} may be greater than or equal to the power supply voltage VDD, and the embodiment of the present disclosure does not limit the specific value of V_{clk}. The clock signal bootstrap circuit may further include a clock generator (not shown) for generating the first clock signal CLK_{P}. The second clock signal CLK_{N} may be input outside the clock signal bootstrap circuit, or may be generated by the clock signal bootstrap circuit according to the first clock signal CLK_{P}. Sources of the first clock signal CLK_{P} and the second clock signal CLK_{N} are not limited in the embodiments of the present disclosure.

Because the first clock signal CLK_{P} and the second clock signal CLK_{N} are a pair of differential signals, and the voltage value of the first clock signal CLK_{P} is 0 to V_{clk}, when CLK_{P} = 0, CLK_{N}=V_{clk}, that is, when the first clock signal is at a low level, the second clock signal is at a high level. Similarly, at CLK_{P}=V_{clk}, CLK_{N} = 0, that is, when the first clock signal is at a high level, the second clock signal is at a low level.

The following describes a relationship between the level of the third clock signal CLK_{BSTP} and the first clock signal CLK_{P} and the second clock signal CLK_{N}.

In a possible implementation, when the first clock signal CLK_{P} is at a low level, the second pole m12 and the third pole m13 of the first transistor conduct, the second pole m32 and the third pole m33 of the third transistor conduct, the second pole m22 and the third pole m23 of the second transistor do not conduct and the gate-source voltage is greater than or equal to 0, the power supply voltage VDD charges the first capacitor C1 through the third transistor, and the third clock signal CLK_{BSTP} is at a low level;

when the first clock signal CLK_{P} is at a high level, the second pole m12 and the third pole m13 of the first transistor do not conduct and the gate-source voltage is less than 0, the second pole m32 and the third pole m33 of the third transistor do not conduct, the second pole m22 and the third pole m23 of the second transistor conduct, the first capacitor C1 is discharged, the third clock signal CLK_{BSTP} is at a high level and the level of the third clock signal CLK_{BSTP} is greater than the level of the first clock signal CLK_{P};

in the case that the high level of the first clock signal CLK_{P} is equal to the power supply voltage, when the second pole and the third pole of the second transistor do not conduct, the gate-source voltage of the second transistor is equal to 0; and

in the case that the high level of the first clock signal CLK_{P} is greater than the power supply voltage, when the second pole and the third pole of the second transistor do not conduct, the gate-source voltage of the second transistor is greater than 0.

Referring to FIG. 7, since the first terminal c11 of the first capacitor receives the first clock signal CLK_{P}, the voltage of the first terminal c11 of the first capacitor is 0 at CLK_{P} = 0.

The first pole m11 of the first transistor receives the second clock signal CLK_{N}, and the second pole m12 of the first transistor receives the first clock signal CLK_{P}, so the voltage of the first pole m11 is V_{clk} and the voltage of the second pole m12 of the first transistor is 0 at CLK_{P} = 0. The first transistor is an N-channel transistor, so the second pole m12 and the third pole m13 of the first transistor conduct. The third pole m13 of the first transistor outputs the third clock signal CLK_{BSTP}, so the voltage value of the third clock signal CLK_{BSTP} is also 0.

The first pole m21 of the second transistor receives the second clock signal CLK_{N}, so the voltage of the first pole m21 of the second transistor is V_{clk} at CLK_{P} = 0. The second transistor is a P-channel transistor, so the second pole m22 and the third pole m23 of the second transistor do not conduct.

The third transistor is a P-channel transistor and CLK_{BSTP} = 0, so the second pole m32 and the third pole m33 of the third transistor conduct. At this time, the power supply voltage VDD charges the first capacitor C1 through the third transistor M3, so that the voltage of the second terminal c12 of the first capacitor C1 is VDD.

The second terminal c12 of the first capacitor C1 is connected to the second pole m22 of the second transistor, so the voltage of the second pole m22 of the second transistor is also VDD. Since V_{clk} is greater than or equal to the power supply voltage VDD, the gate-source voltage (V_{clk}-VDD) of the second transistor is greater than or equal to 0.

In this case, as long as V_{clk} > VDD, the gate-source voltage of the second transistor will be greater than 0, and in the case that the second transistor is a P-channel transistor, the leakage degree of the second transistor will be greatly reduced.

In this way, when the first clock signal is at a high level, the leakage degree of the clock signal generator is reduced, thereby reducing the power consumption of the clock signal generator.

Similarly, at CLK_{P}=V_{clk}, the voltage of the first terminal c11 of the first capacitor is VDD. The first capacitor is discharged, so that the voltage of the second terminal c12 of the first capacitor reaches VDD+V_{clk}.

At CLK_{P}=V_{clk}, CLK_{N} = 0, that is, when the first clock signal CLK_{P} is at a high level, the second clock signal CLK_{N} is at a low level.

The first pole m11 of the first transistor receives the second clock signal CLK_{N}, and the second pole m12 of the first transistor receives the first clock signal CLK_{P}, so the voltage of the first pole m11 of the first transistor is 0 and the voltage of the second pole m12 is V_{clk} at CLK_{P}=V_{clk}. The first transistor is an N-channel transistor, so the second pole m12 and the third pole m13 of the first transistor do not conduct.

The first pole m21 of the second transistor receives the second clock signal CLK_{N}, so the voltage of the first pole m21 of the second transistor is 0 at CLK_{P}=V_{clk}. The second transistor is a P-channel transistor, so the second pole m22 and the third pole m23 of the second transistor conduct.

The voltage of the second terminal c12 of the first capacitor is equal to VDD+V_{clk}, and when the second pole and the third pole of the second transistor conduct, if leakage is not considered, the voltages of the third pole m23 of the second transistor and the first pole m31 of the third transistor are also equal to VDD+V_{clk}, CLK_{BSTP}=VDD+V_{clk}. The third transistor is a P-channel transistor, so the second pole m32 and the third pole m33 of the third transistor do not conduct.

At this time, the voltage difference between the second pole m12 and the third pole m13 of the first transistor is VDD, so the first transistor has leakage. However, since the voltage of the first pole m11 of the first transistor is equal to 0 and the voltage of the second pole m12 is equal to V_{clk}, the gate-source voltage of the first transistor is less than 0, and in the case that the first transistor is an N-channel transistor, the leakage degree of the first transistor will be greatly reduced.

The following describes a relationship between the level of the fourth clock signal CLK_{BSTN} and the first clock signal CLK_{P} and the second clock signal CLK_{N}.

In a possible implementation, when the second clock signal CLK_{N} is at a low level, the second pole m42 and the third pole m43 of the fourth transistor conduct, the second pole m62 and the third pole m63 of the sixth transistor conduct, the second pole m52 and the third pole m53 of the fifth transistor do not conduct and the gate-source voltage is greater than or equal to 0, the power supply voltage charges the second capacitor C2 through the sixth transistor, and the fourth clock signal CLK_{BSTN} is at a low level;

when the second clock signal CLK_{N} is at a high level, the second pole m42 and the third pole m43 of the fourth transistor do not conduct and the gate-source voltage is less than 0, the second pole m62 and the third pole m63 of the sixth transistor do not conduct, the second pole m52 and the third pole m53 of the fifth transistor conduct, the second capacitor is discharged, the fourth clock signal CLK_{BSTN} is at a high level and the level of the fourth clock signal CLK_{BSTN} is greater than the level of the second clock signal CLK_{N};

in the case that the high level of the second clock signal CLK_{N} is equal to the power supply voltage, when the second pole and the third pole of the fifth transistor do not conduct, the gate-source voltage of the fifth transistor is equal to 0; and

in the case that the high level of the second clock signal CLK_{N} is greater than the power supply voltage, when the second pole and the third pole of the fifth transistor do not conduct, the gate-source voltage of the fifth transistor is less than 0.

Referring to FIG. 7, since the first terminal c21 of the second capacitor receives the second clock signal CLK_{N}, and the first clock signal CLK_{P} and the second clock signal CLK_{N} are a pair of differential signals, the voltage of the first terminal c21 of the second capacitor is 0 at CLK_{N}=0, CLK_{P}=V_{clk}. The first pole m41 of the fourth transistor receives the first clock signal CLK_{P}, and the second pole m42 of the fourth transistor receives the second clock signal CLK_{N}, so the voltage of the first pole m41 of the fourth transistor is V_{clk}, and the voltage of the second pole m42 is 0 at CLK_{P}=V_{clk}. The fourth transistor is an N-channel transistor, so the second pole m42 and the third pole m43 of the fourth transistor conduct. The third pole m43 of the fourth transistor outputs the fourth clock signal CLK_{BSTN}, so the voltage value of the fourth clock signal CLK_{BSTN} is also 0.

The first pole m51 of the fifth transistor receives the first clock signal CLK_{P}, so the voltage of the first pole m51 of the fifth transistor is V_{clk} at CLK_{P}=V_{clk}. The fifth transistor is a P-channel transistor, so the second pole m52 and the third pole m53 of the fifth transistor do not conduct.

The sixth transistor is a P-channel transistor and CLK_{BSTP} = 0, so the second pole m62 and the third pole m63 of the sixth transistor conduct. At this time, the power supply voltage VDD charges the second capacitor C2 through the sixth transistor, so that the voltage of the second terminal c22 of the second capacitor is VDD.

The second terminal c22 of the second capacitor is connected to the second pole m52 of the fifth transistor, so the voltage of the second pole m52 of the fifth transistor is also VDD. Since V_{clk} is greater than or equal to the power supply voltage VDD, the gate-source voltage (V_{clk}-VDD) of the fifth transistor is greater than or equal to 0.

In this case, as long as V_{clk} > VDD, the gate-source voltage (V_{clk}-VDD) of the fifth transistor is greater than 0, and in the case that the fifth transistor is a P-channel transistor, the leakage degree of the fifth transistor can be reduced.

Similarly, when CLK_{P} = 0, the voltage of the first terminal c21 of the second capacitor is VDD. The second capacitor is discharged, so that the voltage of the second terminal c22 of the second capacitor reaches VDD+V_{clk}.

When CLK_{P} = 0, CLK_{N}=V_{clk}, the first pole m41 of the fourth transistor receives the first clock signal CLK_{P}, and the second pole m42 of the fourth transistor receives the second clock signal CLK_{N}, so when CLK_{P} = 0, the voltage of the first pole m41 of the fourth transistor is 0, and the voltage of the second pole m42 is V_{clk}. The fourth transistor is an N-channel transistor, so the second pole m42 and the third pole m43 of the fourth transistor do not conduct.

The first pole m51 of the fifth transistor receives the first clock signal CLK_{P}, so the voltage of the first pole m51 of the fifth transistor is 0 at CLK_{P} = 0. The fifth transistor is a P-channel transistor, so the second pole m52 and the third pole m53 of the fifth transistor conduct.

The voltage of the second terminal c22 of the second capacitor is equal to VDD+V_{clk}, and when the second pole m52 and the third pole m53 of the fifth transistor conduct, if leakage is not considered, the voltage of the third pole m53 of the fifth transistor and the voltage of the first pole m61 of the sixth transistor are also equal to VDD+V_{clk}, CLK_{BSTN}=VDD+V_{clk}. The sixth transistor is a P-channel transistor, so the second pole m62 and the third pole m63 of the sixth transistor do not conduct.

At this time, the voltage difference between the second pole m42 and the third pole m43 of the fourth transistor is VDD, so the fourth transistor has leakage. However, since the voltage of the first pole of the fourth transistor is equal to 0 and the voltage of the second pole is equal to V_{clk}, the gate-source voltage of the fourth transistor is less than 0, and in the case that the fourth transistor is an N-channel transistor, the leakage degree of the fourth transistor will be greatly reduced.

In this way, no matter whether the first clock signal is at a high level or a low level, the leakage degree of at least one transistor in the clock signal bootstrap circuit is reduced, thereby reducing the power consumption of the clock signal bootstrap circuit.

Because the clock signal bootstrap circuit can output a differential clock signal, and the differential clock signal can drive a device with higher linearity, a device with a higher linearity provided in the converter is supported, to improve performance of the analog to digital conversion circuit.

Those skilled in the art should understand that the embodiments of the present disclosure do not limit the type of each transistor, and do not limit the type of each electrode of each transistor, as long as the leakage degree of at least one transistor in the clock signal bootstrap circuit is reduced no matter whether the first clock signal is at a high level or a low level.

The clock signal bootstrap circuit of the embodiment of the present disclosure does not involve boosting, and thus does not need to store additional charges, does not need to be provided with a large-area capacitor, and occupies a smaller chip area.

FIG. 8 shows a schematic diagram of another structure of a clock signal bootstrap circuit according to an embodiment of the present disclosure.

As shown in FIG. 8, in a possible implementation, the clock signal bootstrap circuit further includes an inverter, an input terminal of the inverter is connected to the second input terminal w12 of the first bootstrap sub-circuit and the first input terminal w21 of the second bootstrap sub-circuit, an output terminal of the inverter is connected to the first input terminal w11 of the first bootstrap sub-circuit and the second input terminal w22 of the second bootstrap sub-circuit, and the second clock signal is generated by the inverter.

In this case, the input terminal of the inverter, the second input terminal of the first bootstrap sub-circuit, and the first input terminal of the second bootstrap sub-circuit may jointly serve as the input terminal of the clock signal bootstrap circuit, and the output terminal of the first bootstrap sub-circuit and the output terminal of the second bootstrap sub-circuit may respectively serve as the two output terminals of the clock signal bootstrap sub-circuit.

For example, if the clock signal bootstrap circuit receives a single-ended clock signal (such as a first clock signal), an inverter may be added based on the circuit structure of the clock signal bootstrap circuit shown in FIG. 7, so that an input terminal of the inverter is connected to the second input terminal of the first bootstrap sub-circuit and the first input terminal of the second bootstrap sub-circuit, and an output terminal of the inverter is connected to the first input terminal of the first bootstrap sub-circuit and the second input terminal of the second bootstrap sub-circuit. That is, the input terminal of the inverter is connected to the first terminal c11 of the first capacitor, the second pole m12 of the first transistor, the first pole m41 of the fourth transistor, and the first pole m51 of the fifth transistor, and the output terminal of the inverter is connected to the first terminal c21 of the second capacitor, the second pole m42 of the fourth transistor, the first pole m11 of the first transistor, and the first pole m21 of the second transistor.

In this case, the first clock signal is simultaneously input to the second input terminal of the first bootstrap sub-circuit, the first input terminal of the second bootstrap sub-circuit, and the input terminal of the inverter, and the inverter may directly invert the first clock signal to obtain the second clock signal, which is then input to the first input terminal of the first bootstrap sub-circuit and the second input terminal of the second bootstrap sub-circuit.

In this way, the adaptability of the clock signal bootstrap circuit to different application scenarios is improved.

FIG. 9 shows a schematic diagram of a structure of a clock signal generator according to an embodiment of the present disclosure.

As shown in FIG. 9, in a possible implementation, the clock signal generator comprises a boost sub-circuit and a clock buffer sub-circuit,

the boost sub-circuit used for generate at least one voltage signal whose voltage value is greater than a power supply voltage, the voltage signals used for supply power to the clock buffer sub-circuit;

the clock buffer sub-circuit configured to generate at least one pair of clock signals with a swing greater than the first threshold, and output the clock signals to the converter to drive at least a part of the converter.

For example, the clock signal generator may include a boost sub-circuit and a clock buffer sub-circuit, wherein the boost sub-circuit is powered by a power supply voltage less than a first threshold.

The boost sub-circuit may generate a voltage signal whose voltage value is greater than the power supply voltage, and the voltage signal is used to supply power to the clock buffer sub-circuit. The clock buffer sub-circuit is powered by a voltage greater than the first threshold, and therefore can generate a clock signal with a swing greater than the first threshold. On the premise that the boost sub-circuit generates at least one voltage signal, the clock buffer sub-circuit may generate at least one pair of clock signals with a swing greater than a first threshold, and each pair of clock signals includes two differential clock signals. The clock buffer sub-circuit may output the clock signal to the converter to drive at least a part of the converter. Exemplarily, it can be used to drive the key parts described above.

The specific structures of the boost sub-circuit and the clock buffer sub-circuit are not limited in an embodiment of the present disclosure, as long as the boost sub-circuit and the clock buffer sub-circuit can achieve the above functions. Examples of the structures of the boost sub-circuit and the clock buffer sub-circuit are given below.

Only the clock buffer sub-circuit needs a voltage signal whose voltage value is greater than the first threshold to supply power, and the boost sub-circuit, other parts of the converter, and the feedback circuit may still be powered by a power supply voltage lower than the first threshold, so overall power consumption of the analog to digital conversion circuit is relatively low. In addition, the voltage signal obtained by boosting is not provided to the entire analog to digital conversion circuit, and therefore, a large-area capacitor does not need to be provided to additionally store charges, thereby occupying a smaller chip area.

FIG. 10 shows a schematic diagram of structures of a boost sub-circuit and a clock buffer sub-circuit according to an embodiment of the present disclosure.

As shown in FIG. 10, in a possible implementation, the boost sub-circuit comprises a DCDC converter, the clock buffer sub-circuit includes a clock buffer, and the DCDC converter is connected to the clock buffer,

the DCDC converter boosts an input voltage signal to obtain a boosted voltage signal and outputs the boosted voltage signal to the clock buffer, and the clock buffer generates and outputs a pair of clock signals according to the received voltage signal.

For example, if the voltage value of the voltage signal boosted by a single DCDC converter is greater than or equal to the first threshold, the boost sub-circuit only needs to include one DCDC converter. Correspondingly, the clock buffer sub-circuit may also include only one clock buffer. An output terminal of the DCDC converter is connected to an input terminal of the clock buffer, the DCDC converter boosts an input voltage signal to obtain a boosted voltage signal and outputs the boosted voltage signal to the clock buffer, and the clock buffer generates and outputs a pair of clock signals according to the received voltage signal. The clock signal generated by the clock buffer may be a differential clock signal, and the low level of the clock signal may be 0, and the high level may be equal to the voltage value of the received voltage signal.

Both the DCDC converter and the clock buffer can be implemented based on the prior art, and the structures of the DCDC converter and the clock buffer will not be repeated here.

In this way, the structures of the boost sub-circuit and the clock buffer sub-circuit are simpler.

FIG. 11 shows a schematic diagram of structures of a boost sub-circuit and a clock buffer sub-circuit according to an embodiment of the present disclosure.

As shown in FIG. 11, in a possible implementation, the boost sub-circuit includes a plurality of DCDC converters, the power supply voltage is separately input to the plurality of DCDC converters, the clock buffer sub-circuit includes a plurality of clock buffers, and each DCDC converter is connected to one clock buffer.

each DCDC converter boosts an input voltage signal to obtain a boosted voltage signal, and outputs the boosted voltage signal to a clock buffer connected to the DCDC converter, and each clock buffer generates and outputs a pair of clock signals based on the received voltage signal.

For example, as described above, different parts to be driven by the clock signal may have different requirements on the swing of the clock signal, so that the boost sub-circuit may include multiple DCDC converters with different boost capabilities. The power supply voltage is input to a plurality of DCDC converters respectively, each DCDC converter outputs a voltage signal, the voltage values of the voltage signals output by each DCDC converters are different, so that for each part to be driven, the voltage value of the voltage signal output by one DCDC converter is the same as the swing of the clock signal required by the part. Correspondingly, the clock buffer sub-circuit may also include a plurality of clock buffers, and an output terminal of each DCDC converter is connected to an input terminal of one clock buffer. Each clock buffer generates and outputs a pair of clock signals according to the received voltage signal. The clock signal generated by the clock buffer may be a differential clock signal, and the low level of the clock signal may be 0, and the high level may be equal to the voltage value of the received voltage signal, thereby obtaining multiple pairs of clock signals with different swings. In this case, a plurality of pairs of clock signals with different swings can meet requirements of all parts to be driven for the swings of the clock signals.

In this manner, the clock buffer sub-circuit can output a clock signal that meets an application scenario requirement.

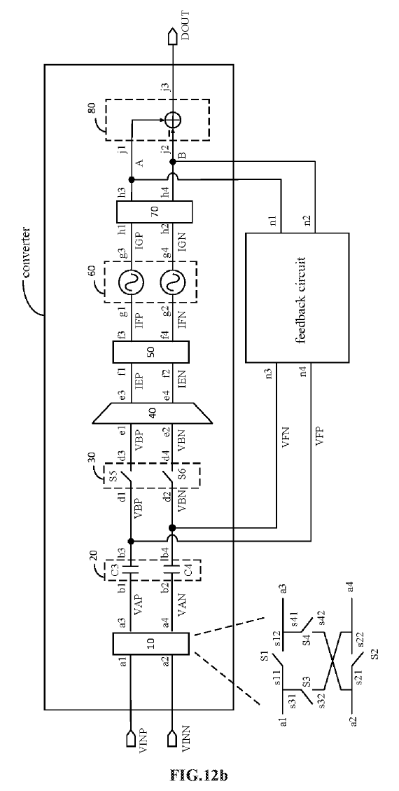

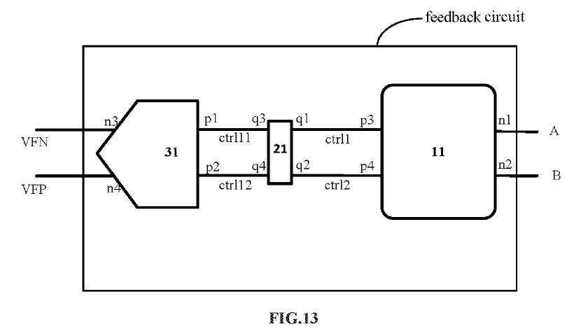

FIGS. 12a and 12b show schematic diagrams of a structure of a converter according to an embodiment of the present disclosure.

As shown in FIG. 12a and FIG. 12b, in a possible implementation, the converter includes a first chopping part 10, a capacitor filtering part 20, a dead zone control part 30, a voltage-current conversion part 40, a second chopping part 50, an integration part 60, a quantization part 70, and an output part 80,

the analog input signal comprises a differential first input signal VINP and a differential second input signal VINN, and the feedback signal comprises a differential first feedback signal VFP and a differential second feedback signal VFN,

a first terminal a1 of the first chopping part receives a first input signal VINP, a second terminal a2 of the first chopping part receives a second input signal VINN, a third terminal a3 of the first chopping part is connected to a first terminal b1 of the capacitor filtering part, and a fourth terminal a4 of the first chopping part is connected to a second terminal b2 of the capacitor filtering part;

a third terminal b3 of the capacitor filtering part is connected to a first terminal d1 of the dead zone control part and a fourth terminal n4 of the feedback circuit, a fourth terminal b4 of the capacitor filtering part is connected to a second terminal d2 of the dead zone control part and a third terminal n3 of the feedback circuit, the fourth terminal n4 of the feedback circuit outputs a first feedback signal VFP, and the third terminal n3 of the feedback circuit outputs a second feedback signal VFN;

a third terminal d3 of the dead zone control part is connected to a first terminal e1 of the voltage-current conversion part, and a fourth terminal d4 of the dead zone control part is connected to a second terminal e2 of the voltage-current conversion part;

a third terminal e3 of the voltage-current conversion part is connected to a first terminal f1 of the second chopping part, and a fourth terminal e4 of the voltage-current conversion part is connected to a second terminal f2 of the second chopping part;

the third terminal f3 of the second chopping part is connected to the first terminal g1 of the integration part, and the fourth terminal f4 of the second chopping part is connected to the second terminal g2 of the integration part;

a third terminal g3 of the integration part is connected to a first terminal h1 of the quantization part, a fourth terminal g4 of the integration part is connected to a second terminal h2 of the quantization part, a third terminal h3 of the quantization part is connected to a first terminal j1 of the output part and a first terminal n1 of the feedback part, and a fourth terminal h4 of the quantization part is connected to a second terminal j2 of the output part and a second terminal n2 of the feedback part;

the third terminal j3 of the output part outputs the digital output signal DOUT.

For example, the converter may comprise a first chopping part, a capacitor filtering part, a dead zone control part, a voltage-current conversion part, a second chopping part, an integration part, a quantization part, and an output part.

The first chopping part may receive an externally input analog input signal. The analog input signal may be a differential signal, including a first input signal and a second input signal. In this case, the first chopping part, the capacitor filtering part, the dead zone control part, the voltage-current conversion part, the second chopping part, the integration part, and the quantization part each include two input terminals and two output terminals, and the output part may include two input terminals and one output terminal.

A first terminal of the first chopping part receives a first input signal, a second terminal of the first chopping part receives a second input signal, a third terminal of the first chopping part outputs a signal VAP obtained by chopping the first input signal, and a fourth terminal of the first chopping part outputs a signal VAN obtained by chopping the second input signal.

As shown in FIG. 12b, the first chopping part may include switches S1-S4. The first terminal s11 of S1 is connected to the first terminal s31 of S3 and be used as the first terminal of the first chopping part. The second terminal s12 of S1 is connected to the first terminal s41 of S4 and be used as the third terminal of the first chopping part. The first terminal s21 of S2 is connected to the second terminal s42 of S4 and be used as the second terminal of the first chopping part. The second terminal s22 of S2 is connected to the second terminal s32 of S3 and be used as the fourth terminal of the first chopping part.

Those skilled in the art should understand that the first chopping part may also be implemented by adopting other structures, as long as it may have a chopping function and may chop a differential input signal to obtain a differential output signal, and embodiments of the present disclosure do not limit the specific structure of the first chopping part.

The signal VAP and the signal VAN are respectively output by the first chopping part and then input to the first terminal and the second terminal of the capacitor filtering part. As shown in FIG. 12b, the capacitor filtering part may include a capacitor C3 and a capacitor C4. one terminal of the capacitor C3 be used as the first terminal of the capacitor filtering part, and the other terminal of the capacitor C3 be used as the third terminal of the capacitor filtering part; one terminal of the capacitor C4 be used as the second terminal of the capacitor filtering part, and the other terminal of the capacitor C4 be used as the fourth terminal of the capacitor filtering part.

The capacitor C3 may be used to filter out an interference component in the signal VAP. The capacitor C4 may be used to filter out interference components in the signal VAN. Since the third terminal of the capacitor filtering part is further connected to the fourth terminal of the feedback circuit, the fourth terminal of the capacitor filtering part is further connected to the third terminal of the feedback circuit, the feedback signal output by the feedback circuit is a differential signal and includes the first feedback signal VFP and the second feedback signal VFN, and the fourth terminal and the third terminal of the feedback circuit respectively output the first feedback signal VFP and the second feedback signal VFN, after the interference component in the signal VAP is filtered out, the swing is adjusted by the first feedback signal VFP, and the signal VBP can be obtained and output to the first terminal of the dead zone control part. After the interference component in the signal VAN is filtered out, the swing is adjusted by the second feedback signal VFN to obtain the signal VBN and output it to the second terminal of the dead zone control part.

As shown in FIG. 12b, the dead zone control part may include a switch S5 and a switch S6. One terminal of the switch S5 be used as the first terminal of the dead zone control part, and the other terminal be used as the third terminal of the dead zone control part; one terminal of the switch S6 be used as the second terminal of the dead zone control part, and the other terminal be used as the fourth terminal of the dead zone control part. The third terminal of the dead zone control part is connected to the first terminal of the voltage-current conversion part, the fourth terminal of the dead zone control part is connected to the second terminal of the voltage-current conversion part, and the signal VBP and the signal VBN enter the voltage-current conversion stage described above after entering the voltage-current conversion part, so that the switch S5 and the switch S6 can be controlled to be turned off within a small period of time in each cycle (the cycle frequency can be the sampling frequency of the analog to digital conversion circuit) to prevent the signal VBP and the signal VBN from entering the voltage-current conversion part, so as to optimize the quality of the signal output by the voltage-current conversion part (for example, remove the glitch in the signal output by the voltage-current conversion part). The time periods for controlling the switch S5 and the switch S6 to be turned off may be set according to application scenario requirements, which is not limited in the embodiments of the present disclosure.

The voltage-current conversion part may convert the input signal VBP into the current signal IEP. The input signal VBN is converted into a current signal IEN. The function of the voltage-current conversion part may be implemented by a transconductance amplifier in the prior art, which will not be repeated here.

The current signal IEP may be input to the first terminal of the second chopping part, and the current signal IEN may be input to the second terminal of the second chopping part. The structure and function of the second chopping part may be the same as those of the first chopping part, which will not be repeated here. The third terminal of the second chopping part outputs a signal IFP obtained by chopping the signal IEP, and the fourth terminal outputs a signal IFN obtained by chopping the signal IEN.

As shown in FIG. 12b, the integration part may include a first integrator and a second integrator. The signal IFP may be input to one terminal of the first integrator (the first terminal of the integration part), the first integrator integrates the signal IFP, and outputs the signal IGP through the other terminal (the third terminal of the integration part). The signal IFN may be input to one terminal of the second integrator (the second terminal of the integration part), the second integrator integrates the signal IFN, and outputs the signal IGN through the other terminal (the fourth terminal of the integration part). The first integrator and the second integrator may be implemented based on the prior art, and the structures of the first integrator and the second integrator will not be repeated here.

The signal IGP may be input to the first terminal of the quantization part, and the signal IGN may be input to the second terminal of the quantization part. The quantization part may quantize the signal IGP into a numerical value A, and quantize the signal IGN into a numerical value B, where the numerical value A may be output through a third terminal of the quantization part, and the numerical value B may be output through a fourth terminal of the quantization part. The quantization part may be implemented based on the prior art, and the structure of the quantization part will not be repeated here.

The numerical value A may be input to a first terminal of the output part, and the numerical value B may be input to a second terminal of the output part. As shown in FIG. 12b, the output part may perform a subtraction operation on the numerical value A and the numerical value B, and use an operation result as the digital output signal DOUT. The digital output signal DOUT may be output by the third terminal of the output part. The output part may be implemented based on the prior art, and the specific structure of the output part will not be repeated here.

Referring to FIG. 12a, the numerical value A and the numerical B are also input to the feedback circuit. The feedback circuit may output the first feedback signal VFP and the second feedback signal VFN according to the numerical value A and the numerical value B. For a structure of the feedback circuit and an example in which the feedback circuit achieves the foregoing function, refer to FIG. 10.

In a possible implementation, the quantization part is a time domain quantization part, the integration part is a time domain integration part, and the quantization part and the integration part are implemented by using a digital circuit.

For example, because the time domain integration part and the time domain quantization part are characterized in that signal processing is performed in the time domain and signal processing is not performed in the analog domain, both the time domain integration part and the time domain quantization part may be implemented by using digital circuits. The digital circuit can operate at a low voltage (especially a digital circuit under an advanced process, the more advanced the process, the lower the voltage at which the process can operate), so the time domain integration part and the time domain quantization part can maintain high performance at a power supply voltage lower than the first threshold. This further increases the proportion of digital circuits in the analog to digital conversion circuit, and further reduces the power consumption of the analog to digital conversion circuit.

In a possible implementation, the clock signal is used for driving the first chopping part, the dead zone control part, and the second chopping part.

It is mentioned above that the clock signal output by the clock signal generator may be used to drive at least a part of the converter. In an example, the first chopping part, the dead zone control part, and the second chopping part may be driven.

In a possible implementation, the swing of the clock signal used to drive the dead zone control part is greater than or equal to a second threshold, the swing of the clock signal used to drive the first chopping part and the second chopping part is greater than or equal to a third threshold, and the second threshold is greater than the third threshold.

For example, the higher the swing of the clock signal, the better the effect of driving the first chopping part, the dead zone control part, and the second chopping part, but the greater the power consumption. Therefore, the clock signal for driving the first chopping part, the dead zone control part, and the second chopping part may be determined according to the requirements of the first chopping part, the dead zone control part, and the second chopping part on the swing of the clock signal.

A requirement of the first chopping part and the second chopping part on the swing of the clock signal may be equal to a third threshold (for example, 0.9 V). The dead zone control part has a higher requirement on the swing of the clock signal, which may be equal to the second threshold (e.g., 1.1 V). The swing of the first pair of clock signals output by the clock signal bootstrap circuit may be 0.9 V, the swing of the second pair of clock signals may be 1V, and the swing of the third pair of clock signals may be 1.1 V, in this case, the first chopping part and the second chopping part can be driven by the first pair of clock signals, and the dead zone control part can be driven by the third pair of clock signals.

If the swing of the pair of clock signals with the lowest swing output by the clock signal generator has exceeded the second threshold, the pair of clock signals with the lowest swing may be used for driving the first chopping part, the dead zone control part, and the second chopping part.

That is, the swing of the clock signal used to drive the dead zone control part is greater than or equal to the second threshold, the swing of the clock signal used to drive the first chopping part and the second chopping part is greater than or equal to the third threshold, and the second threshold is greater than the third threshold.

In this manner, power consumption of the analog to digital conversion circuit can be reduced while quality of the analog to digital conversion is ensured.

FIG. 13 shows a schematic diagram of a structure of a feedback circuit according to an embodiment of the present disclosure.

As shown in FIG. 13, in a possible implementation, the feedback circuit comprises a logic control part, a third chopping part, and a capacitive digital to analog conversion part,

a first terminal of the logic control part be used as the first terminal of the feedback circuit, a second terminal of the logic control part be used as the second terminal of the feedback circuit, a third terminal of the logic control part is connected to the first terminal of the third chopping part, and a fourth terminal of the logic control part is connected to the second terminal of the third chopping part;

a third terminal of the third chopping part is connected to the first terminal of the capacitive digital to analog conversion part, and a fourth terminal of the third chopping part is connected to the second terminal of the capacitive digital to analog conversion part; and

the third terminal of the capacitive digital to analog conversion part be used as the third terminal of the feedback circuit, and the fourth terminal of the capacitive digital to analog conversion part be used as the fourth terminal of the feedback circuit.

For example, the feedback circuit as a whole may be implemented by using digital circuits, and may include a logic control part 11, a third chopping part 21, and a capacitive digital to analog conversion part 31.

The first terminal n1 of the logic control part be used as the first terminal of the feedback circuit to receive the numerical value A, and the second terminal n2 of the logic control part be used as the second terminal of the feedback circuit to receive the numerical value B. Based on the numerical values A and B, the logic control part may obtain digital control signals, which may be differential signals, including signals ctrl1 and ctrl2. The digital control signals used for control an adjustment degree of the analog input signal by the feedback circuit. The logic control part may be implemented based on the prior art, and the specific implementation of the logic control part will not be repeated here.

The third terminal p3 of the logic control part may be connected to the first terminal q1 of the third chopping part, the fourth terminal p4 of the logic control part may be connected to the second terminal q2 of the third chopping part, and the signal ctrl1 and the signal ctrl2 are input to the third chopping part for chopping. The signal ctrl1 is chopped to obtain a signal ctrl 11, and the signal ctrl2 is chopped to obtain a signal ctrl22. The third chopping part may be implemented based on the prior art, and the specific implementation of the third chopping part will not be repeated here.

The third terminal q3 of the third chopping part may input the signal ctrl11 to the first terminal p1 of the capacitive digital to analog conversion part, and the fourth terminal q4 of the third chopping part may input the signal ctrl22 to the second terminal p2 of the capacitive digital to analog conversion part. The capacitive digital to analog conversion part may perform digital to analog conversion on the signal ctrl11 to obtain a signal VFN, and perform digital to analog conversion on the signal ctrl22 to obtain a signal VFP, where the signal VFP and the signal VFN may be analog signals. In this case, the signal VFP may be operated with the signal VAP, and the signal VFN may be operated with the signal VAN. The third terminal n3 of the capacitive digital to analog conversion part may output a signal VFN, and the fourth terminal n4 may output a signal VFP. The capacitive digital to analog conversion part may be implemented based on the prior art, and the specific implementation of the capacitive digital to analog conversion part will not be repeated here.

An embodiment of the present disclosure further provides a chip, including the analog to digital conversion circuit described above. For a schematic diagram of a structure of the chip, refer to FIG. 4.

An embodiment of the present disclosure further provides an electronic apparatus, including the chip described above. The electronic apparatus may be a terminal device or a server, and embodiments of the present disclosure do not limit the specific type of the electronic apparatus.

The flowchart and block diagrams in the drawings illustrate the architecture, functionality, and operation of possible implementations of systems, methods and computer program products according to various an embodiment of the present disclosure. In this regard, each block in the flowchart or block diagrams may represent a circuit, program segment or part of an instructions, which comprises one or more executable instructions for implementing the specified logical function(s). In some alternative implementations, the functions noted in the blocks may occur out of the order noted in the drawings. For example, two blocks shown in succession may, in fact, be executed substantially concurrently, or the blocks may sometimes be executed in the reverse order, depending upon the functionality involved. It will also be noted that each block of the block diagrams and/or flowchart, and combinations of blocks in the block diagrams and/or flowchart diagrams, can be implemented by special purpose hardware-based systems that perform the specified functions or acts, or combinations of special purpose hardware and computer instructions.

The descriptions of the various embodiments of the present disclosure have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

What is claimed is:

1. An analog to digital conversion circuit, comprising a clock signal generator, a converter, and a feedback circuit, wherein a power supply voltage of the clock signal generator, the converter, and the feedback circuit is less than or equal to a first threshold,
the clock signal generator configured to generate at least one pair of clock signals with a swing greater than the first threshold, and output the clock signals to the converter to drive at least a part of the converter;
the converter configured to obtain a digital output signal based on an analog input signal and a feedback signal; and
the feedback circuit configured to generate the feedback signal based on a latest digital output signal and output the feedback signal to the converter.

2. The analog to digital conversion circuit according to claim 1, wherein the converter comprises a first chopping part, a capacitor filtering part, a dead zone control part, a voltage-current conversion part, a second chopping part, an integration part, a quantization part, and an output part,
the analog input signal comprises differential first input signal and second input signal, and the feedback signal comprises differential first feedback signal and second feedback signal,
a first terminal of the first chopping part receives the first input signal, a second terminal of the first chopping part receives the second input signal, a third terminal of the first chopping part is connected to a first terminal of the capacitor filtering part, and a fourth terminal of the first chopping part is connected to a second terminal of the capacitor filtering part;
a third terminal of the capacitor filtering part is connected to a first terminal of the dead zone control part and a fourth terminal of the feedback circuit, the fourth terminal of the capacitor filtering part is connected to a second terminal of the dead zone control part and a third terminal of the feedback circuit, the fourth terminal of the feedback circuit outputs the first feedback signal, and the third terminal of the feedback circuit outputs the second feedback signal;
a third terminal of the dead zone control part is connected to a first terminal of the voltage-current conversion part, and a fourth terminal of the dead zone control part is connected to a second terminal of the voltage-current conversion part;
a third terminal of the voltage-current conversion part is connected to a first terminal of the second chopping part, and a fourth terminal of the voltage-current conversion part is connected to a second terminal of the second chopping part;
a third terminal of the second chopping part is connected to the first terminal of the integration part, and a fourth terminal of the second chopping part is connected to the second terminal of the integration part;
a third terminal of the integration part is connected to a first terminal of the quantization part, a fourth terminal of the integration part is connected to a second terminal of the quantization part, the third terminal of the quantization part is connected to a first terminal of the output part and a first terminal of the feedback circuit, and the fourth terminal of the quantization part is connected to a second terminal of the output part and a second terminal of the feedback circuit; and
a third terminal of the output part outputs the digital output signal.

3. The analog to digital conversion circuit according to claim 2, wherein the quantization part is a time domain quantization part, the integration part is a time domain integration part, and the quantization part and the integration part are implemented by using a digital circuit.

4. The analog to digital conversion circuit according to claim 2, wherein the clock signal is configured to driving the first chopping part, the dead zone control part, and the second chopping part.

5. The analog to digital conversion circuit according to claim 4, wherein the clock signal generator includes at least one cascaded clock signal bootstrap circuit, each clock signal bootstrap circuit outputs a pair of clock signals, a clock signal output by a previous-stage clock signal bootstrap circuit is used as a clock signal input by a post-stage clock signal bootstrap circuit, and a swing of the clock signal output by the post-stage clock signal bootstrap circuit is higher than a swing of the clock signal output by the previous-stage clock signal bootstrap circuit.

6. The analog to digital conversion circuit according to claim 5, wherein a swing of a clock signal used to drive the dead zone control part is greater than or equal to a second threshold, a swing of a clock signal used to drive the first chopping part and the second chopping part is greater than or equal to a third threshold, and the second threshold is greater than the third threshold.

7. The analog to digital conversion circuit according to claim 5, wherein the feedback circuit comprises a logic control part, a third chopping part, and a capacitive digital to analog conversion part,
a first terminal of the logic control part is used as the first terminal of the feedback circuit, a second terminal of the logic control part is used as the second terminal of the feedback circuit, a third terminal of the logic control part is connected to the first terminal of the third chopping part, and a fourth terminal of the logic control part is connected to the second terminal of the third chopping part;
a third terminal of the third chopping part is connected to the first terminal of the capacitive digital to analog conversion part, and a fourth terminal of the third chopping part is connected to the second terminal of the capacitive digital to analog conversion part; and
a third terminal of the capacitive digital to analog conversion part is used as the third terminal of the feedback circuit, and a fourth terminal of the capacitive digital to analog conversion part is used as the fourth terminal of the feedback circuit.

8. The analog to digital conversion circuit according to claim 5, wherein the clock signal bootstrap circuit comprises a first bootstrap sub-circuit and a second bootstrap sub-circuit, the first bootstrap sub-circuit comprises a first transistor, a second transistor, a third transistor, and a first capacitor, and the second bootstrap sub-circuit comprises a fourth transistor, a fifth transistor, a sixth transistor and a second capacitor,
a first pole of the first transistor is connected to a first pole of the second transistor and is used as a first input terminal of the first bootstrap sub-circuit, a second pole of the first transistor is connected to a first terminal of the first capacitor and is used as a second input terminal of the first bootstrap sub-circuit, a third pole of the first transistor is connected to a third pole of the second transistor and a first pole of the third transistor and is used as an output terminal of the first bootstrap sub-circuit, a second pole of the second transistor is connected to a second pole of the third transistor and a second terminal of the first capacitor, and a third pole of the third transistor is connected to a power supply voltage;
a first pole of the fourth transistor is connected to a first pole of the fifth transistor and is used as a first input terminal of the second bootstrap sub-circuit, a second pole of the fourth transistor is connected to a first terminal of the second capacitor and is used as a second input terminal of the second bootstrap sub-circuit, a third pole of the fourth transistor is connected to a third pole of the fifth transistor and a first pole of the sixth transistor and is used as an output terminal of the second bootstrap sub-circuit, a second pole of the fifth transistor is connected to a second pole of the sixth transistor and a second terminal of the second capacitor, and a third pole of the sixth transistor is connected to a power supply voltage;
a first input terminal of the second bootstrap sub-circuit is connected to a second input terminal of the first bootstrap sub-circuit to receive a first clock signal, a second input terminal of the second bootstrap sub-circuit is connected to the first input terminal of the first bootstrap sub-circuit to receive a second clock signal, an output terminal of the first bootstrap sub-circuit outputs a third clock signal, and an output terminal of the second bootstrap sub-circuit outputs a fourth clock signal; and
the first clock signal and the second clock signal are a pair of differential signals and are used as clock signals input by the clock signal bootstrap circuit, and the third clock signal and the fourth clock signal are a pair of differential signals being clock signals output by the clock signal bootstrap circuit.

9. The analog to digital conversion circuit according to claim 8, further comprising an inverter, an input terminal of the inverter is connected to the second input terminal of the first bootstrap sub-circuit and the first input terminal of the second bootstrap sub-circuit, an output terminal of the inverter is connected to the first input terminal of the first bootstrap sub-circuit and the second input terminal of the second bootstrap sub-circuit, and the second clock signal is generated by the inverter.

10. The analog to digital conversion circuit according to claim 8, wherein
based on that the first clock signal is at a low level, the second pole and the third pole of the first transistor conduct, the second pole and the third pole of the third transistor conduct, the second pole and the third pole of the second transistor do not conduct and the gate-source voltage is greater than or equal to 0, the power supply voltage charges the first capacitor through the third transistor, and the third clock signal is at a low level;
based on that the first clock signal is at a high level, the second pole and the third pole of the first transistor do not conduct and the gate-source voltage is less than 0, the second pole and the third pole of the third transistor do not conduct, the second pole and the third pole of the second transistor conduct, the first capacitor is discharged, the third clock signal is at a high level and the level of the third clock signal is greater than the level of the first clock signal;
based on that the high level of the first clock signal is equal to the power supply voltage, responsive to the second pole and the third pole of the second transistor being non-conducting, the gate-source voltage of the second transistor is equal to 0; and
based on that the high level of the first clock signal is greater than the power supply voltage, when the second pole and the third pole of the second transistor do not conduct, the gate-source voltage of the second transistor is greater than 0.

11. The analog to digital conversion circuit according to claim 8, wherein
based on that the second clock signal is at a low level, the second pole and the third pole of the fourth transistor conduct, the second pole and the third pole of the sixth transistor conduct, the second pole and the third pole of the fifth transistor do not conduct and the gate-source voltage is greater than or equal to 0, the power supply voltage charges the second capacitor through the sixth transistor, and the fourth clock signal is at a low level;
based on that the second clock signal is at a high level, the second pole and the third pole of the fourth transistor do not conduct and the gate-source voltage is less than 0, the second pole and the third pole of the sixth transistor do not conduct, the second pole and the third pole of the fifth transistor conduct, the second capacitor is discharged, the fourth clock signal is at a high level and the level of the fourth clock signal is greater than the level of the second clock signal;
based on that the high level of the second clock signal is equal to the power supply voltage, responsive to the second pole and the third pole of the fifth transistor being non-conducting, the gate-source voltage of the fifth transistor is equal to 0; and
based on that the high level of the second clock signal is greater than the power supply voltage, responsive to the second pole and the third pole of the fifth transistor being non-conducting, the gate-source voltage of the fifth transistor is greater than 0.

12. The analog to digital conversion circuit according to claim 1, wherein the clock signal generator comprises a boost sub-circuit and a clock buffer sub-circuit,
the boost sub-circuit is configured to generate at least one voltage signal whose voltage value is greater than the power supply voltage, and the voltage signal is configured to supply power to the clock buffer sub-circuit; and
the clock buffer sub-circuit configured to generate at least one pair of clock signals with a swing greater than the first threshold, and output the clock signals to the converter to drive at least a part of the converter.

13. The analog to digital conversion circuit according to claim 12, wherein the boost sub-circuit comprises a plurality of DCDC converters, the power supply voltage is input to the plurality of DCDC converters respectively, the clock buffer sub-circuit comprises a plurality of clock buffers, and each DCDC converter is connected to one clock buffer,
each DCDC converter boosts an input voltage signal to obtain a boosted voltage signal, and outputs the boosted voltage signal to a clock buffer connected to the DCDC converter, and each clock buffer generates and outputs a pair of clock signals based on the received voltage signal.

14. The analog to digital conversion circuit according to claim 12, wherein the boost sub-circuit comprises a DCDC converter, the clock buffer sub-circuit comprises a clock buffer, and the DCDC converter is connected to the clock buffer,
the DCDC converter boosts an input voltage signal to obtain a boosted voltage signal and outputs the boosted voltage signal to the clock buffer, and the clock buffer generates and outputs a pair of clock signals based on a received voltage signal.

15. A chip, comprising an analog to digital conversion circuit, the analog to digital conversion circuit comprises a clock signal generator, a converter, and a feedback circuit, wherein a power supply voltage of the clock signal generator, the converter, and the feedback circuit is less than or equal to a first threshold,
the clock signal generator configured to generate at least one pair of clock signals with a swing greater than the first threshold, and output the clock signals to the converter to drive at least a part of the converter;
the converter configured to obtain a digital output signal based on an analog input signal and a feedback signal; and
the feedback circuit configured to generate the feedback signal based on a latest digital output signal and output the feedback signal to the converter.

16. An electronic apparatus, comprising a chip, the chip comprises an analog to digital conversion circuit, the analog to digital conversion circuit comprises a clock signal generator, a converter, and a feedback circuit, wherein a power supply voltage of the clock signal generator, the converter, and the feedback circuit is less than or equal to a first threshold,
the clock signal generator configured to generate at least one pair of clock signals with a swing greater than the first threshold, and output the clock signals to the converter to drive at least a part of the converter;
the converter configured to obtain a digital output signal based on an analog input signal and a feedback signal; and
the feedback circuit configured to generate the feedback signal based on a latest digital output signal and output the feedback signal to the converter.
